(19) United States
(12) Patent Application Publication
(10) Pub. No.: US 2018/0061867 A1
(43) Pub. Date: Mar. 1, 2018

(54) METHODS OF PROTECTING SEMICONDUCTOR OXIDE CHANNEL IN HYBRID TFT PROCESS FLOW

(71) Applicant: Apple Inc., Cupertino, CA (US)

(72) Inventors: Chih Pang Chang, Toufen City (TW); Jung-Fang Chang, Tainan (TW); ChinWei Hu, Hsinchu (TW); Te-Hua Teng, Tainan (TW); Jung Yen Huang, Zhubei City (TW); Wen-I Hsieh, Hsinchu (TW); Jiun-Jye Chang, Cupertino, CA (US); Ching-Sang Chuang, Sunnyvale, CA (US); Hung-Che Ting, Taipei City (TW); Lungpao Hsin, Kaohsiung (TW)

(21) Appl. No.: 15/344,045

(22) Filed: Nov. 4, 2016

Related U.S. Application Data
(60) Provisional application No. 62/382,151, filed on Aug. 31, 2016.

(51) Int. Cl. H01L 27/12

(52) U.S. Cl. CPC H01L 27/1251; H01L 27/1225; H01L 27/1288; H01L 27/1248; H01L 27/127; H01L 27/124

(57) ABSTRACT

Hybrid silicon TFT and oxide TFT structures and methods of formation are described. In an embodiment, a protection layer is formed over a semiconductor oxide channel layer of the oxide TFT to protect the semiconductor oxide channel layer during a cleaning operation of the silicon TFT.

### RELATED APPLICATIONS

This application claims the benefit of priority of U.S. Provisional Application No. 62/382,151 filed Aug. 31, 2016, which is incorporated herein by reference.

### BACKGROUND

### Field

Embodiments described herein relate to an active matrix display, and more specifically to a display panel with hybrid TFT layout.

### Background Information

Display panels such as liquid crystal display (LCD) and organic light emitting diode (OLED) display panels are commonly found in electronic devices such as cellular telephones, portable computers, televisions, wearable devices, etc. Both LCD and OLED technologies utilize thin film transistors (TFTs) in formation of the pixel circuitry or gate driver circuitry (e.g. gate in panel) found within the display panel.

Traditional TFT technology includes amorphous silicon (a-Si) TFTs and low temperature poly silicon (LTPS) TFTs. LTPS provides for greater charge carrier mobility compared to a-Si, which can be useful for scaling to high resolution displays. The LTPS process however, may include a greater number of masks steps than the a-Si process.

More recently semiconductor oxide TFTs have been proposed as a new version of LTPS, with higher charge carrier mobilities than a-Si, and less mask steps than the LTPS process. LTPS TFTs may possess attributes such as high switching speed and drive current compared to semiconductor oxide TFTs, while semiconductor oxide TFTs may possess attributes such as low leakage current and better TFT uniformity compared to LTPS TFTs.

### SUMMARY

Hybrid silicon TFT and oxide TFT structures and methods of protecting a semiconductor oxide channel layer in hybrid TFT process flows are described. In particular, structures and process flows are described that may be used to protect the semiconductor oxide channel layer during a cleaning operation of the silicon channel layer of the silicon TFT. In an embodiment, a permanent electrically conductive protection layer is formed between the semiconductor oxide channel layer and source-drain contacts of the oxide TFT. In other embodiments, a sacrificial protection layer is formed over the semiconductor oxide channel layer, and removed after cleaning the silicon TFT channel layer.

### BRIEF DESCRIPTION OF THE DRAWINGS

FIGS. 1A-1E are cross-sectional side view illustrations of a method of forming a hybrid TFT structure with an electrically conductive protection layer in accordance with an embodiment.

FIG. 1F is a flow chart illustrating a method of forming a hybrid TFT structure with an electrically conductive protection layer in accordance with an embodiment.

FIGS. 2A-2F are cross-sectional side view illustrations of a method of forming a hybrid TFT structure with a temporary protection layer in accordance with an embodiment.

FIG. 2G is a flow chart illustrating a method of forming a hybrid TFT structure with a temporary protection layer in accordance with an embodiment.

FIGS. 3A-3F are cross-sectional side view illustrations of a method of forming a hybrid TFT structure with a temporary protection layer in accordance with an embodiment.

FIG. 3G is a flow chart illustrating a method of forming a hybrid TFT structure with a temporary protection layer in accordance with an embodiment.

### DETAILED DESCRIPTION

Embodiments describe display panels with hybrid TFT structures and methods of protecting a semiconductor oxide channel in hybrid TFT process flows. In an embodiment, a hybrid transistor structure includes a silicon TFT and an oxide TFT. A common metal layer is patterned to form first source-drain contacts to the silicon TFT and second source-drain contacts to the oxide TFT. In an embodiment, the oxide TFT includes a semiconductor oxide channel layer, and an electrically conductive protection layer between the semiconductor oxide channel layer and the second source-drain contacts.

In an embodiment, the hybrid transistor structure includes a silicon channel layer, and a dielectric layer over the silicon channel layer. In order to form the first source-drain contacts, openings are formed in the dielectric layer to expose the silicon channel layer. In accordance with embodiments, a fluorine-based cleaning operation may be performed prior to forming the source-drain contacts in order to remove any native oxide that has formed on the silicon channel layer, and reduce contact resistance of the first source-drain contacts to the silicon channel layer.

In one aspect, embodiments describe structures and methods of protecting the semiconductor oxide channel during the fluorine-based cleaning operation for the silicon TFT. In one embodiment, the semiconductor oxide channel is protected by an electrically conductive protection layer that remains on the semiconductor oxide channel after formation of the source-drain contacts. In other embodiments, processes are described in which a temporary protection layer is used to protect the semiconductor oxide channel during the fluorine-based cleaning operation and then removed prior to formation of the source-drain contacts.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, and “on” as used herein may refer to a relative position of one layer with respect to other layers. One layer “over” or “on” another layer or bonded “to” or in “contact” with another layer may be directly in contact with the other layer or may have one or more intervening layers. One layer “between” layers may be directly in contact with the layers or may have one or more intervening layers.

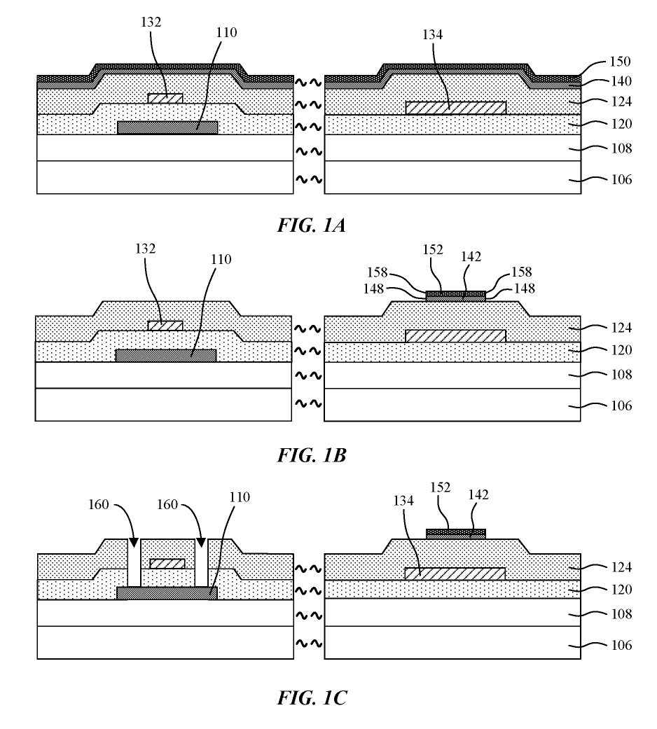

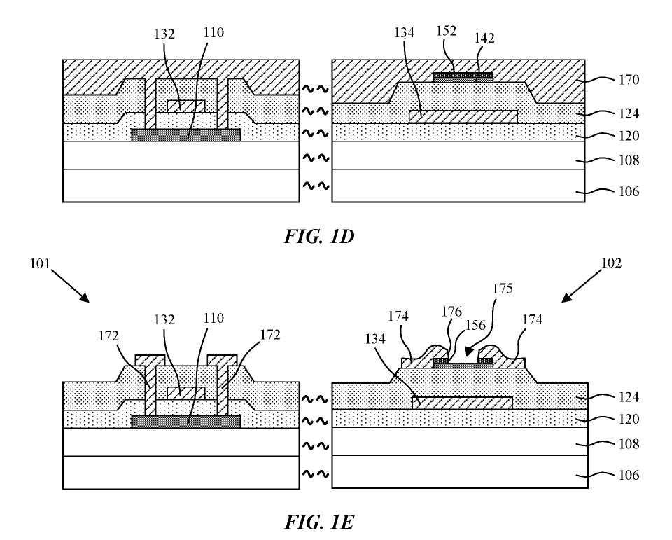

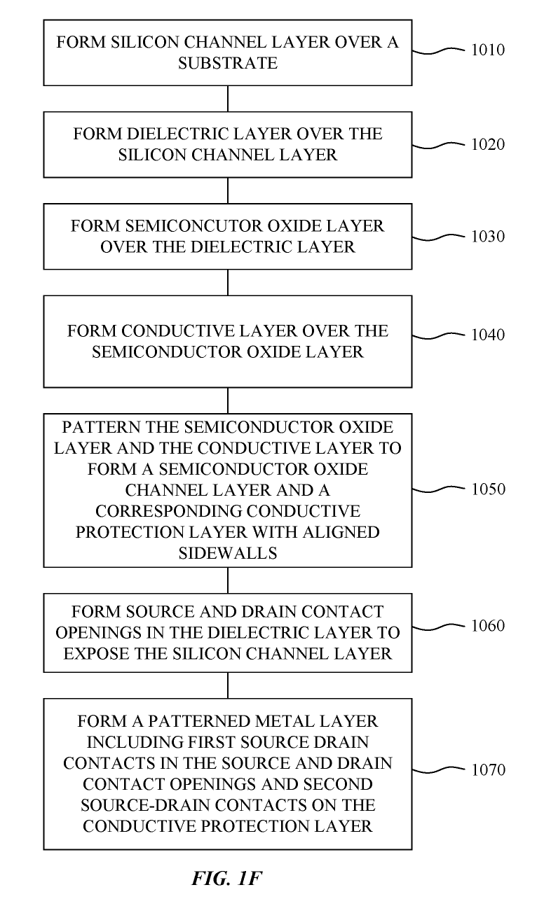

Referring now to FIGS. 1A-1E cross-sectional side view illustrations are provided of a method of forming a hybrid TFT structure with an electrically conductive protection layer in accordance with an embodiment. In the following illustrations and description, close-up illustrations are provided side-by-side of two TFT regions, such as a silicon TFT region and a semiconductor oxide TFT region formed on the same substrate. In a specific embodiment, the silicon TFT region includes a bottom gate transistor, and the semiconductor oxide TFT region includes a top gate transistor. The two TFT regions and transistors may share many of the same layers and materials. The two TFT regions and transistors may additionally be formed together within a same pixel circuit within the display area of a display panel, together within a gate in panel region outside of the display area of a display panel, or a combination thereof.

As shown in FIG. 1A, a buffer layer 108 may optionally be formed on a substrate 106, such as glass or plastic substrate. Buffer layer 108 may optionally be formed of a materials such as silicon nitride (SiNx) or silicon oxide (SiOx), or combinations thereof. A silicon channel layer 110 is then formed over the substrate 106. For example, this may be formed by using a suitable deposition technique such as chemical vapor deposition (CVD) and etching. In an embodiment, silicon channel layer 110 is a polysilicon layer for the formation of an LTPS transistor. A dielectric layer is then formed over the silicon channel layer 110. The dielectric layer may include one or more layers. In an embodiment, the dielectric layer includes a gate dielectric layer 120 that is formed over the silicon channel layer 110. For example, the gate dielectric layer 120 may be a silicon oxide SiOx layer, formed using a suitable deposition technique such as CVD.

A patterned metal layer may then be formed over the gate dielectric layer 120 including a top gate layer 132 (for the LTPS transistor) and a bottom gate layer 134 (for the semiconductor oxide transistor). The gate layers 132, 134 may be formed of one or more metal layers with each layer made of a material such as molybdenum (Mo), tungsten (W), titanium (Ti), and aluminum (Al). In an embodiment, the gate layers 132, 134 are formed by sputtering, and etching.

An interlayer dielectric (ILD) 124 may then be formed over the gate dielectric layer 120, the top gate layer 132, and the bottom gate layer 134. ILD 124 may include one or more dielectric layers. For example, ILD 124 may include a layer stack of SiNx and SiOx, formed using a suitable deposition technique such as CVD.

Still referring to FIG. 1A, a semiconductor oxide layer 140 is then formed on the ILD 124, followed by the formation of a conductive (electrically conductive) layer 150 over the semiconductor oxide layer 140. As illustrated, each of the semiconductor oxide layer 140 and conductive layer 150 may be blanket deposited over the silicon TFT region and the semiconductor oxide TFT region. In an embodiment, the semiconductor oxide layer 140 is formed of a material such as indium gallium zinc oxide (IGZO), however this is merely illustrative, and a variety of other semiconductor oxide materials may be used such as, but not limited to, zinc tin oxide (ZTO) and zinc indium oxide (ZIO). The semiconductor oxide layer 140 may be amorphous. In an embodiment, semiconductor oxide layer 140 is formed using a suitable technique such as sputtering. In an embodiment, conductive layer 150 is formed using a suitable technique such as sputtering, and may have a thickness between 1,000 angstroms and several hundreds of angstroms. In accordance with embodiments, the conductive layer 150 may be formed of a metal such as of Mo, W, Pd, Pt, Cu, Ag, Au, TiW, and Cr, or a metal oxide such as indium tin oxide (ITO) or indium zinc oxide (IZO).

Referring now to FIG. 1B the conductive layer 150 and semiconductor oxide layer 140 are then patterned to form a layer stack including a semiconductor oxide channel layer 142 and corresponding conductive protection layer 152. As shown, exterior sidewalls 158 of the conductive protection layer 152 and exterior sidewalls 148 of the semiconductor oxide channel layer 142 are aligned. Source and drain contact openings 160 are then formed through the ILD 124 and gate dielectric layer 120 as illustrated in FIG. 1C to expose the silicon channel layer 110. In an embodiment, ILD 124 and gate dielectric layer 120 are dry etched, and may be etched at the same time.

Following the formation of source and drain contact openings 160, a cleaning process may be performed in accordance with embodiments. For example, a cleaning process may be performed to remove any oxide that has formed on the silicon channel layer, such as an oxide layer formed during dry etching of the ILD and gate dielectric layer 120, for example when dry etching includes O₂, or a native oxide layer that may form. In accordance with embodiments, the cleaning operation may be fluorine-based, such as vapor HF or a buffered HF wet etch. The conductive protection layer 152 may be formed of a material such as a metal or metal oxide, with a thickness and chemical resistance to protect the semiconductor oxide channel layer 142 during the cleaning operation in order to preserve the integrity of the semiconductor oxide TFT.

Referring now to FIGS. 1D-1E, a second metal layer 170 may be formed over the substrate, for example, by sputtering followed by etching to form first source-drain contacts 172 in the source and drain contact openings 160 and second source-drain contacts 174 on the conductive protection layer 152. In the particular embodiment illustrated in FIG. 1E, etching to form the second source-drain contacts 174 further includes removing a portion of the conductive protection layer 152 such that the second source-drain contacts 174 have interior sidewalls 176 that are aligned with interior sidewalls 156 of the conductive protection layer 152. In an embodiment, the conductive protection layer 152 is completely removed between the second source-drain contacts 174. In an embodiment, etching to form the second source-drain contacts 174 further includes removing a portion (e.g. reducing a thickness) of the semiconductor oxide channel layer 142 between the second source-drain contacts 174.

In the embodiment illustrated, the hybrid transistor structure includes a substrate 106, a silicon TFT 101 on the substrate 106, and an oxide TFT 102 on the substrate 106, and a patterned metal layer including first source-drain contacts 172 to the silicon TFT and second source-drain contacts 174 to the oxide TFT 102. The oxide TFT 102 may include a semiconductor oxide channel layer 142, and an electrically conductive protection layer 152 between the semiconductor oxide channel layer 142 and the second source-drain contacts 174. An opening 175 may be formed completely through the patterned metal layer forming the second source-drain contacts 174 and the conductive protection layer 152 over the semiconductor oxide channel layer 142, such that the second source-drain contacts 174 and the conductive protection layer 152 have aligned interior sidewalls 176, 156. In the embodiment illustrated, the conductive protection layer 152 and the semiconductor oxide channel layer 142 have aligned exterior sidewalls 158, 148. Still referring to FIG. 1E, in the hybrid transistor structure illustrated, the first source-drain contacts 172 extend through the gate dielectric layer 120 and the ILD 124, and the semiconductor oxide channel layer 142 and the second source-drain contacts 174 are on top of the ILD 124.

FIG. 1F is a flow chart illustrating a method of forming a hybrid TFT structure with an electrically conductive protection layer in accordance with an embodiment. At operation 1010 a silicon channel layer 110 is formed over a substrate 106. At operation 1020 a dielectric layer is formed over the silicon channel layer 110. For example, the dielectric layer may correspond to the gate dielectric layer 120, ILD 124, or both. At operation 1030 a semiconductor oxide layer 140 is formed over the dielectric layer, and at operation 1040 a conductive layer 150 is formed over the semiconductor oxide layer 140. The semiconductor oxide layer and the conductive layer are patterned at operation 1050 to form a semiconductor oxide channel layer 142 and a corresponding conductive protection layer 152 with aligned exterior sidewalls 148, 158. Source and drain contact openings 160 are formed in the dielectric layer at operation 1060 to expose the silicon channel layer 110. At operation 1070 a patterned metal layer is formed including first source-drain contacts 172 in the source and drain contact openings 160 and second source-drain contacts 174 on the conductive protection layer 152. In accordance with embodiment, the method may additionally include performing a fluorine-based cleaning operation on the exposed silicon channel layer 110 after operation 1060 and prior to operation 1070.

In accordance with embodiments, additional aspects and processes may be associated with the operations, and additional operations may be performed, for example as described and illustrated with regard to FIGS. 1A-1E. In an embodiment, forming the patterned metal layer including second source-drain contacts 174 may additionally include etching the conductive layer such that the second source-drain contacts 174 and the conductive protection layer 152 have aligned interior sidewalls 176, 156. In an embodiment, forming the patterned metal layer including second source-drain contacts 174 additionally includes partially removing a portion (e.g. a thickness) of the semiconductor oxide channel layer 142 between the second source-drain contacts 174.

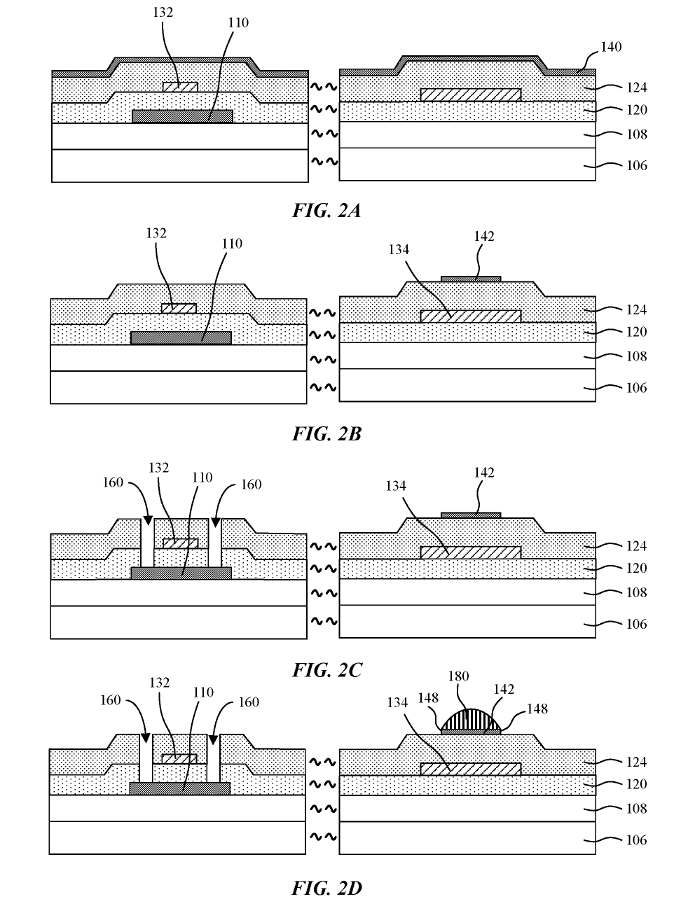

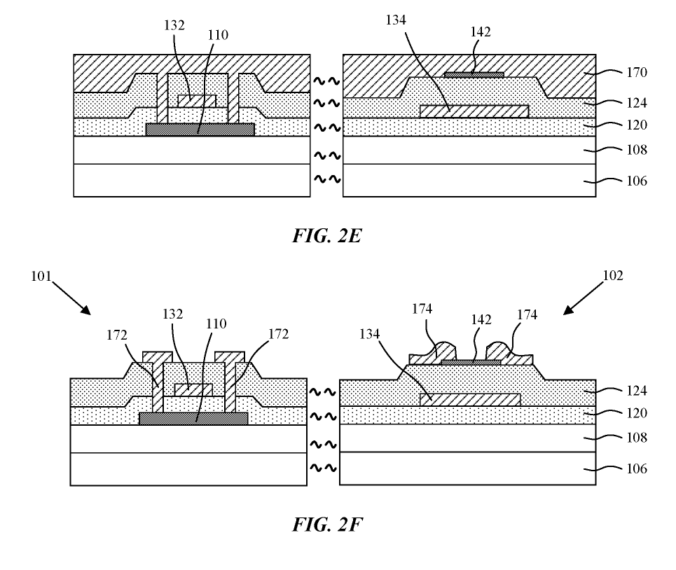

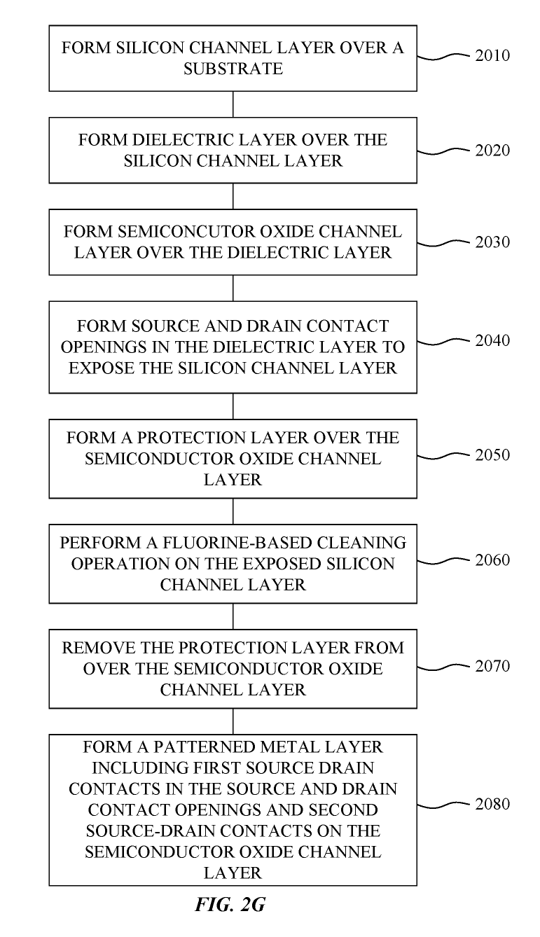

Referring now to FIGS. 2A-2F, cross-sectional side view illustrations are provided of a method of forming a hybrid TFT structure with a temporary protection layer in accordance with an embodiment. The method, structures, and materials presented in FIGS. 2A-2F include many similarities to those previously discussed with regard to FIGS. 1A-1E and FIG. 1F. Accordingly, in interests of conciseness, and to not obscure the embodiments, discussions of many similarities may not be repeated in the followed description of FIGS. 2A-2F.

The structure illustrated in FIG. 2A may be substantially similar to that previously described and illustrated with regard to FIG. 1A with omission of the conductive layer 150. Referring to FIG. 2B, the semiconductor oxide channel layer 142 is formed similarly as described with regard to FIG. 1B, followed by formation of the source and drain contact openings 160 at FIG. 2C similarly as described with regard to FIG. 1C. Referring to FIG. 2D, in an embodiment, a protection layer 180 is formed over the semiconductor oxide channel layer 142. Protection layer 180 may be any suitable material that can provide chemical protection for the semiconductor oxide channel layer 142 during a cleaning operation of the silicon channel layer 110. In an embodiment, protection layer 180 is formed of a resist material. For example, protection layer 180 may be formed by deposition and etching. In an embodiment, protection layer 180 does not cover exterior sidewalls 148 of the semiconductor oxide channel layer 142. In an embodiment, protection layer 180 is formed around the exterior sidewalls 148 of the semiconductor oxide channel layer 142. In one embodiment, the protection layer 180 is reflowed after patterning. For example, this may facilitate covering the semiconductor oxide channel layer 142 top surface and exterior sidewalls 148. Following the formation of the protection layer 180, a fluorine-based cleaning operation may be performed as previously described with regard to FIG. 1C. Following the cleaning operation, the protection layer 180 may be removed. A second metal layer 170 may then be formed and patterned to form first source-drain contacts 172 in the source and drain contact openings 160, and second source-drain contacts 174 on the semiconductor oxide channel layer 142 as illustrated in FIGS. 2E-2F, and similar to the previous descriptions of FIGS. 1D-1E without the conductive protection layer 152.

FIG. 2G is a flow chart illustrating a method of forming a hybrid TFT structure with a temporary protection layer in accordance with an embodiment. At operation 2010 a silicon channel layer 110 is formed over a substrate 106. At operation 2020 a dielectric layer is formed over the silicon channel layer 110. For example, the dielectric layer may correspond to the gate dielectric layer 120, ILD 124, or both. At operation 2030 a semiconductor oxide channel layer 142 is formed over the dielectric layer, for example, by deposition and etching. Source and drain contact openings 160 are formed in the dielectric layer at operation 2040 to expose the silicon channel layer 110.

A protection layer 180 is then formed over the semiconductor oxide channel layer 142 at operation 2050. For example, protection layer 180 may be formed by deposition and etching. In an embodiment, protection layer 180 does not cover exterior sidewalls 148 of the semiconductor oxide channel layer 142. In an embodiment, protection layer 180 is formed around the exterior sidewalls 148 of the semiconductor oxide channel layer 142. In one embodiment, the protection layer 180 is reflowed after patterning. For example, this may facilitate covering the semiconductor oxide channel layer 142 top surface and exterior sidewalls 148.

A fluorine-based cleaning operation may be performed on the exposed silicon channel layer 110 at operation 2060, followed by removal of the protection layer 180 from over the semiconductor oxide channel layer 142 at operation 2070. At operation 2080 a patterned metal layer is formed including first source-drain contacts 172 in the source and drain contact openings 160 and second source-drain contacts 174 on the semiconductor oxide channel layer 142. In accordance with embodiments, additional aspects and processes may be associated with the operations, and additional operations may be performed, for example as described and illustrated with regard to FIGS. 2A-2F.

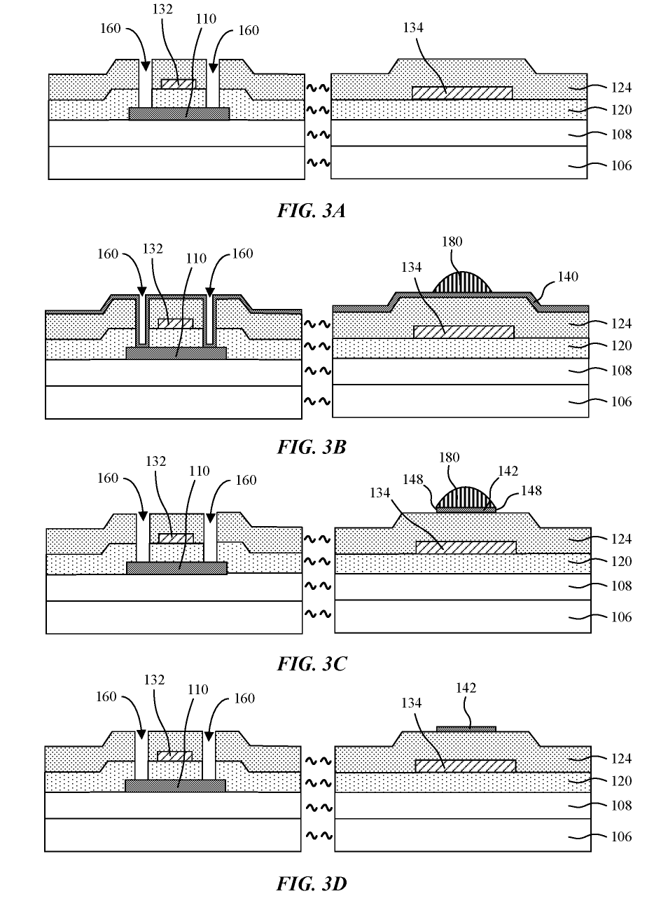

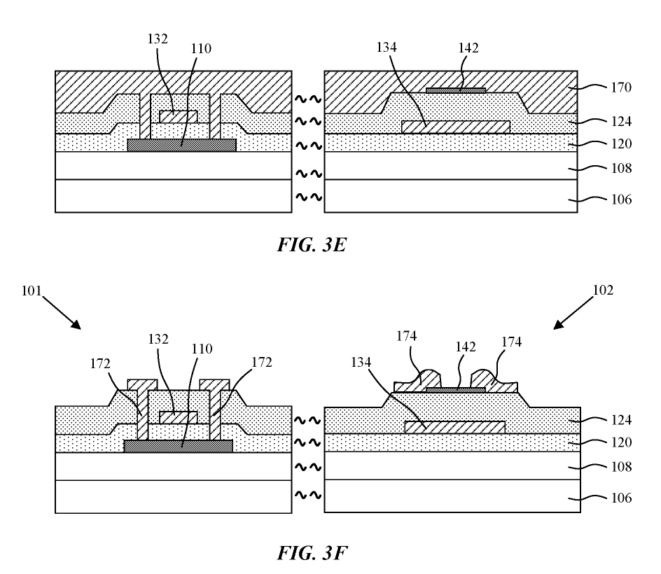

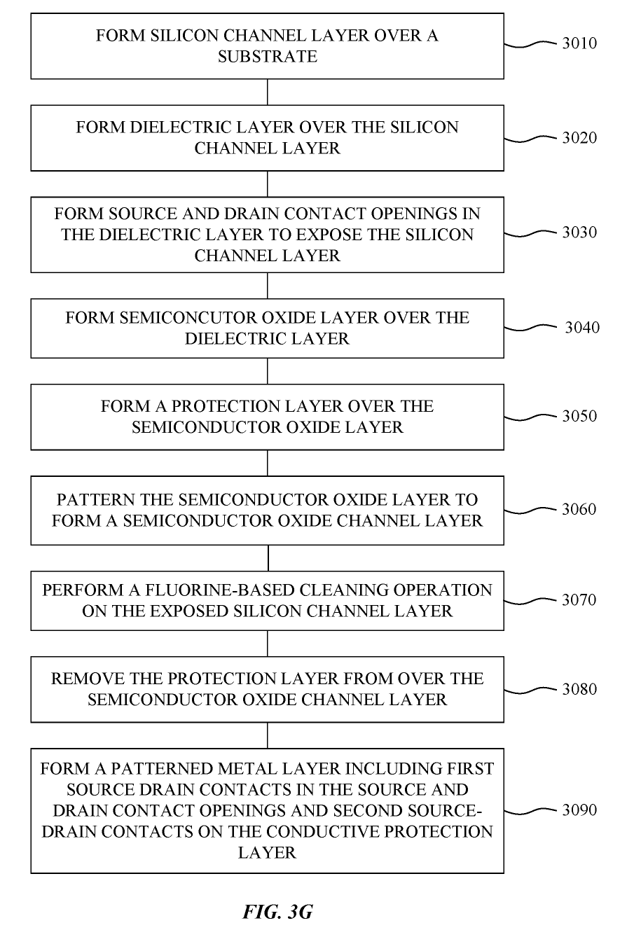

Referring now to FIGS. 3A-3F, cross-sectional side view illustrations are provided of a method of forming a hybrid TFT structure with a temporary protection layer in accordance with an embodiment. The method, structures, and materials presented in FIGS. 3A-3F include many similarities to those previously discussed with regard to FIGS. 2A-2F and FIG. 2G. Accordingly, in interests of conciseness, and to not obscure the embodiments, discussions of many similarities may not be repeated in the followed description of FIGS. 3A-3F.

The structure illustrated in FIG. 3A may be substantially similar to that previously described and illustrated with regard to FIG. 2C with a difference being that the source and drain contact openings 160 have been formed prior to formation of the semiconductor oxide channel layer 142. Referring to FIG. 3B, a semiconductor oxide layer 140 is formed over the substrate 106 and within the source and drain contact openings 160. More specifically, the semiconductor oxide layer 140 may be formed over the ILD 124 and within the source and drain contact openings 160 formed in the ILD 124 and gate dielectric layer 120. Still referring to FIG. 3B, a protection layer 180 is formed over the semiconductor oxide layer 140.

Referring now to FIG. 3C, the semiconductor oxide layer 140 is etched, using the protection layer 180 as an etch mask to define exterior sidewalls 148 of the semiconductor oxide channel layer 142. Protection layer 180 may be any of the materials previously described, including resist. As shown in FIG. 3B, the semiconductor oxide layer 140 may be completely removed from the source and drain contact openings 160. In an embodiment, protection layer 180 does not cover exterior sidewalls 148 of the semiconductor oxide channel layer 142. In one embodiment, the protection layer 180 is reflowed after etching the semiconductor oxide layer 140. For example, this may facilitate covering the semiconductor oxide channel layer 142 top surface and exterior sidewalls 148.

Following etching of semiconductor oxide channel layer 142, and optionally reflowing of the protection layer 180, a fluorine-based cleaning operation may be performed as previously described with regard to FIG. 1C. Following the cleaning operation, the protection layer 180 may be removed as illustrated in FIG. 3D. A second metal layer 170 may then be formed and patterned to form first source-drain contacts 172 in the source and drain contact openings 160, and second source-drain contacts 174 on the semiconductor oxide channel layer 142 as illustrated in FIGS. 3E-3F, and similar to the previous descriptions of FIGS. 1D-1E without the conductive protection layer 152.

FIG. 3G is a flow chart illustrating a method of forming a hybrid TFT structure with a temporary protection layer in accordance with an embodiment. At operation 3010 a silicon channel layer 110 is formed over a substrate 106. At operation 3020 a dielectric layer is formed over the silicon channel layer 110. For example, the dielectric layer may correspond to the gate dielectric layer 120, ILD 124, or both. Source and drain contact openings 160 are formed in the dielectric layer at operation 3030 to expose the silicon channel layer 110. At operation 3040 a semiconductor oxide layer 140 is formed over the dielectric layer, for example, by deposition and etching.

A protection layer 180 is then formed over the semiconductor oxide layer 140 at operation 3050. For example, protection layer 180 may be formed by deposition and etching. At operation 3060 the semiconductor oxide layer 140 is patterned to form a semiconductor oxide channel layer 142. In an embodiment, the protection layer 180 may be used as an etch mask to define the semiconductor oxide channel layer 142.

In an embodiment, protection layer 180 does not cover exterior sidewalls 148 of the semiconductor oxide channel layer 142 after etching the semiconductor oxide layer 140. In one embodiment, the protection layer 180 is reflowed after etching. For example, this may facilitate covering the semiconductor oxide channel layer 142 top surface and exterior sidewalls 148.

A fluorine-based cleaning operation may be performed on the exposed silicon channel layer 110 at operation 3070, followed by removal of the protection layer 180 from over the semiconductor oxide channel layer 142 at operation 3080. At operation 3090 a patterned metal layer is formed including first source-drain contacts 172 in the source and drain contact openings 160 and second source-drain contacts 174 on the semiconductor oxide channel layer 142. In accordance with embodiments, additional aspects and processes may be associated with the operations, and additional operations may be performed, for example as described and illustrated with regard to FIGS. 3A-3F.

In utilizing the various aspects of the embodiments, it would become apparent to one skilled in the art that combinations or variations of the above embodiments are possible for forming a hybrid TFT structure with a protected semiconductor oxide channel. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

1. A hybrid transistor structure comprising:
a substrate;
a silicon TFT on the substrate;
an oxide TFT on the substrate;
a patterned metal layer including first source-drain contacts to the silicon TFT and second source-drain contacts to the oxide TFT;
wherein the oxide TFT includes a semiconductor oxide channel layer, and an electrically conductive protection layer between the semiconductor oxide channel layer and the second source-drain contacts.

2. The hybrid transistor structure of claim 1, further comprising an opening completely through the patterned metal layer and the conductive protection layer over the semiconductor oxide channel layer, such that the second source-drain contacts and the conductive protection layer have aligned interior sidewalls.

3. The hybrid transistor structure of claim 2, wherein the conductive protection layer and the semiconductor oxide channel layer have aligned exterior sidewalls.

4. The hybrid transistor structure of claim 3, wherein the conductive protection layer comprises a metal layer or metal oxide layer.

5. The hybrid transistor structure of claim 4, wherein the conductive protection layer comprises a metal layer formed of a metal selected from the group consisting of Mo, W, Pd, Pt, Cu, Ag, Au, TiW, and Cr.

6. The hybrid transistor structure of claim 4, wherein the conductive protection layer comprises a metal oxide layer selected from the group consisting of ITO and IZO.

7. The hybrid transistor structure of claim 4, further comprising:
a silicon channel layer on the substrate;
a gate dielectric layer over the silicon channel layer; and
an interlayer dielectric (ILD) over the gate dielectric layer;
wherein the first source-drain contacts extend through the gate dielectric layer and the ILD; and
wherein the semiconductor oxide channel layer and the second source-drain contacts are on top of the ILD.

8. The hybrid transistor structure of claim 7, further comprising a second patterned metal layer on the gate dielectric layer, the second patterned metal layer including a top gate layer for the silicon TFT, and a bottom gate layer for the oxide TFT.

9-20. (canceled)
